(19) United States
(12) Patent Application Publication
(10) Pub. No.: US 2007/0148537 A1
(43) Pub. Date: Jun. 28, 2007

(54) Electronic apparatus

(75) Inventors: Masato Nakatani, Kawaguchi-shi (JP); Yasuyuki Suzuki, Tokyo (JP); Yosuke Miura, Chiba-shi (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Kabushiki Kaisha Toshiba

(21) Appl. No.: 11/583,348

(22) Filed: Oct. 18, 2006

(30) Foreign Application Priority Data
Dec. 26, 2005 (JP) P2005-373538

(51) Int. Cl. H01M 2/10; H05K 5/00

(52) U.S. Cl. 429/100; 361/679

(57) ABSTRACT

According to one embodiment, there is provided an electronic apparatus including: a case including a first opening, and a second opening adjacent to the first opening; a first lid that is detachably attached to the case and configured to close the first opening, the first lid including a first edge portion; and a second lid that is detachably attached to the case and configured to close the second opening, while overlapping with a least a part of the first edge portion of the first lid that is attached to the first opening.

### CROSS-REFERENCE TO RELATED APPLICATIONS

This application is based upon and claims the benefit of priority from Japanese Patent Application No. 2005-373538, filed Dec. 26, 2005, the entire contents of which are incorporated herein by reference.

### BACKGROUND

1. Field

One embodiment of the invention relates to an electronic apparatus having a housing portion that is covered by a detachable lid, and more particularly to a configuration for attaching the detachable lid.

2. Description of the Related Art

An electronic apparatus such as a portable computer includes a housing portion such as a battery housing portion and a card housing portion. The housing portion is exposed to the outside of a case through an opening that is opened in an outer wall of the case. The user houses a functional component such as a battery or a memory card in the housing portion through the opening.

The electronic apparatus further includes a lid that is detachably attached to the case. After the functional component is housed in the housing portion, the lid is attached to the case to close the opening. The user detaches the lid to cause the housing portion to be again exposed to the outside of the case so that, for example, the user can replace a battery or add a memory card.

For example, Japanese Patent Application Publication (KOKAI) No. 10-124172 and U.S. Pat. No. 6,043,977 disclose an information processing apparatus that has such a housing portion, and in which the ventilation performance in a case is improved. The information processing apparatus disclosed in the publications has a battery housing portion and a card housing portion. The card housing portion is disposed in adjacent to the battery housing portion.

A battery pack is attached into the battery housing portion of the information processing apparatus. The bottom wall of the battery pack has a function of a lid that closes an opening of the battery housing portion. By contrast, a lid is attached to the case correspondingly with the card housing portion to close an opening of the card housing portion.

Japanese Patent Application Publication (KOKAI) No. 6-119082 discloses an information processing apparatus in which a lid for an HDD cannot be detached unless a battery is detached. The lid for HDD disclosed in the publication is configured so that the lid for HDD is interfered with a peripheral edge of the battery and is prevented from being detached from a case unless the battery is detached.

In the information processing apparatus disclosed in Japanese Patent Application Publication (KOKAI) No. 10-124172 and U.S. Pat. No. 6,043,977, for example, the bottom wall of the battery pack covers the battery housing portion, and the lid covers the card housing portion. The bottom wall of the battery pack (hereinafter, referred to as “battery lid”) and the lid of the card housing portion (hereinafter, referred to as “card lid”) are apposed to the case. Therefore, for example, an area of the lower wall of the case which is a total of the area of the battery lid and that of the card lid is occupied by the members functioning as a lid.

Also in the information processing apparatus disclosed in Japanese Patent Application Publication (KOKAI) No. 6-119082, for example, an area of the case which is a total of the area of the battery lid and that of the HDD lid is occupied by the members functioning as a lid.

By contrast, recent electronic apparatuses are requested to be further miniaturized. When members functioning as a lid occupy a large area of a case, it is impossible to reduce the size of the case, and hence an electronic apparatus is hardly miniaturized.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to an embodiment of the invention;

FIG. 2 is an exemplary perspective view showing a lower wall of the portable computer shown in FIG. 1;

FIG. 3 is an exemplary perspective view of a battery cover shown in FIG. 2;

FIG. 4 is an exemplary perspective view of an HDD cover shown in FIG. 2;

FIG. 5 is an exemplary plan view of the portable computer shown in FIG. 2; and

FIG. 6 is an exemplary section view of the portable computer taken along the line A-A in FIG. 5.

### DETAILED DESCRIPTION

Various embodiments according to the invention will be described hereinafter with reference to the accompanying drawings. In general, according to one embodiment of the invention, there is provided an electronic apparatus including: a case including a first opening, and a second opening adjacent to the first opening; a first lid that is detachably attached to the case and configured to close the first opening, the first lid including a first edge portion; and a second lid that is detachably attached to the case and configured to close the second opening, while overlapping with at least a part of the first edge portion of the first lid that is attached to the first opening.

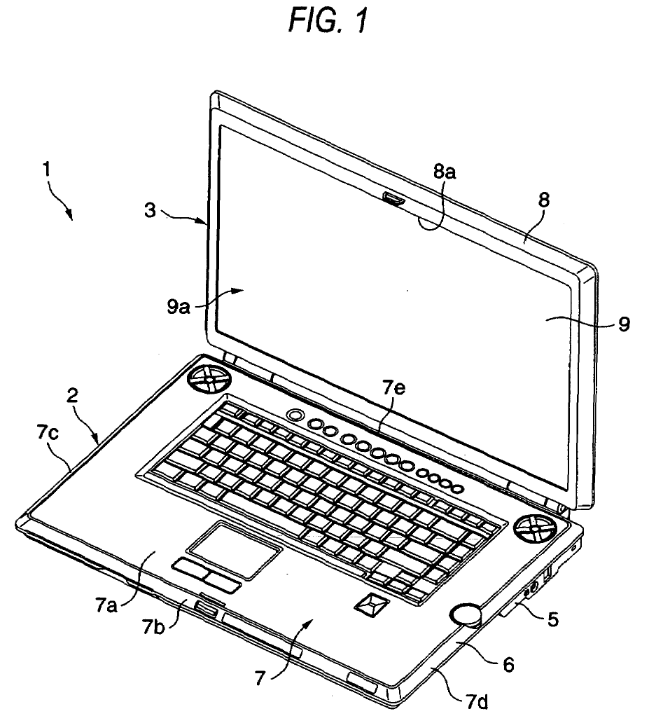

FIGS. 1 to 6 disclose a portable computer 1 that is an electronic apparatus according to an embodiment of the invention. FIG. 1 shows the whole of the portable computer 1. The portable computer 1 includes a body 2 and a display unit 3.

As shown in FIG. 1, the body 2 includes a body base 5 and a body cover 6. The body cover 6 is attached to the body base 5 from the upper side. The body base 5 and the body cover 6 combine with each other so that the body 2 forms a box-like case 7 having an upper wall 7a, a front wall 7b, a left wall 7c, a right wall 7d, a rear wall 7e, and a lower wall 7f. The lower wall 7f is one example of the outer wall.

As shown in FIG. 1, the display unit 3 includes a display housing 8, and a liquid crystal display panel 9 that is housed in the display housing 8. The liquid crystal display panel 9 has a display screen 9a. The display screen 9a is exposed to the outside of the display housing 8 through a front opening 8a of the display housing 8.

The display unit 3 is supported by a rear end portion of the case 7 via a hinge device, which is not shown. Therefore, the display unit 3 is swingable between a close position where the unit is leaned so as to cover the upper wall 7a from the upper side, and an open position where the unit is raised so as to expose the display screen 9a.

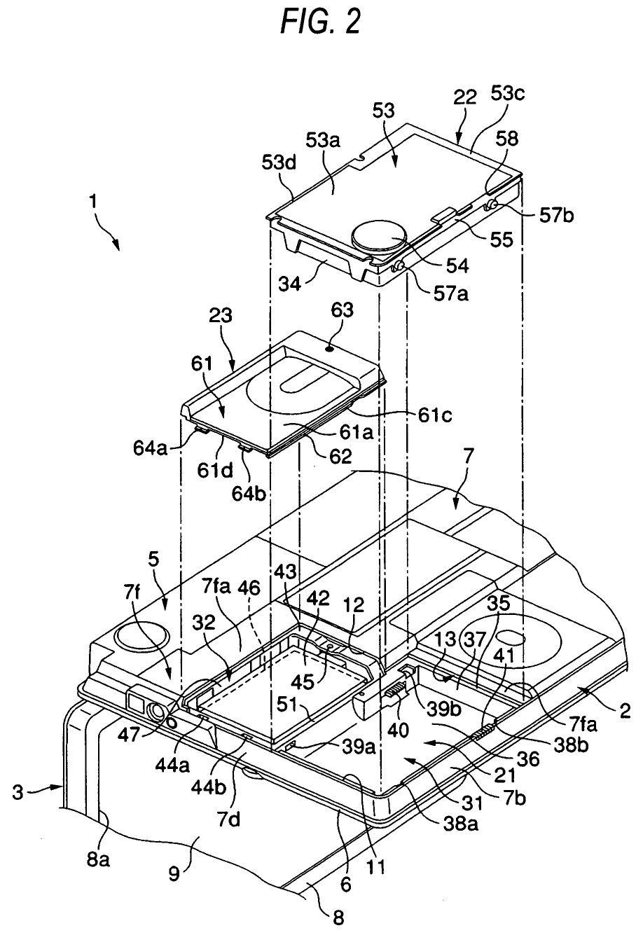

As shown in FIG. 2, the case 7 has a first opening 11 and a second opening 12. The first opening 11 is opened to the outside of the case 7 in a front right end portion of the lower wall 7f. The first opening 11 is formed into a rectangular shape along the front wall 7b and right wall 7d of the case 7. The second opening 12 is opened to the outside of the case 7 in a middle right end portion of the lower wall 7f which is adjacent to the first opening 11. The second opening 12 is formed into a rectangular shape along the right wall 7d of the case 7 and the first opening 11.

The first opening 11 and the second opening 12 communicate with each other in end portions which are adjacent to each other. Therefore, the first opening 11 and the second opening 12 form one large opening 13 together.

As shown in FIG. 2, the body 2 includes a housing portion 21, a battery cover 22, and an HDD cover 23. The housing portion 21 is divided into a battery housing portion 31 and an HDD housing portion 32. The battery housing portion 31 is one example of the first housing portion. The HDD housing portion 32 is one example of the second housing portion. The battery cover 22 is one example of the first lid. The HDD cover 23 is one example of the second lid.

The battery housing portion 31 detachably houses a battery 34. The battery 34 is one example of the first functional component. The battery housing portion 31 is a region that is allowed to be freely opened and closed by the user, i.e., a region that is open to the user, and that is easily accessed by the user.

The battery housing portion 31 is disposed in the case 7 and in a front right end portion of the case 7. Namely, the battery housing portion 31 is disposed correspondingly with the first opening 11, and exposed to the outside of the case 7 through the first opening 11.

The opening 13 has a first support wall 35. The first support wall 35 extends in the opening 13 toward the inside of the opening 13 from an opening edge that is adjacent to the battery housing portion 31. The first support wall 35 is recessed from the lower wall 7f of the case 7 toward the inner side of the thickness direction of the case 7 by a distance equal to the thickness of the battery cover 22, and extends in parallel with the lower wall 7f of the case 7.

The battery housing portion 31 has a bottom wall 36 and a side wall 37. The bottom wall 36 is an inner wall that separates the battery housing portion 31 from the internal space of the case 7. The side wall 37 extends from a peripheral edge of the bottom wall 36 toward the first support wall 35, and is connected to the tip end of first support wall 35.

In the side wall 37 of the battery housing portion 31, a pair of guide groove 38a, 38b are disposed in a portion which is opposed to the front wall 7b of the case 7. The guide groove 38a, 38b extends in the thickness direction of the case 7. In the side wall 37, a pair of engagement recesses 39a, 39b are disposed in a portion which is opposed to the rear wall 7e of the case 7. The engagement recesses 39a, 39b are engagement holes that are recessed toward the outside of the battery housing portion 31. A power source connector 40 is disposed in the battery housing portion 31. The battery 34, which is housed in the battery housing portion 31 is electrically connected to the power source connector 40.

A locking mechanism 41 is disposed in a front end portion of the case 7. The locking mechanism 41 fixes the battery cover 22 attached to the case 7 so that the cover is not detached from the case 7.

As shown in FIG. 2, the HDD housing portion 32 detachably houses an HDD (Hard Disk Drive) 42. The HDD 42 is one example of the second functional component. The HDD 42 is a component which is detached much less frequently than the battery 34. Usually, the HDD 42 is not detached by the user, but detached in maintenance of the portable computer 1 by the non-user such as the manufacturer. The HDD housing portion 32 is a region that is not recommended to be freely opened and closed by the user, i.e., a region that is not open to the user.

The HDD 42 is supplied with the power source from the battery 34 to operate. When the battery 34 is detached from the battery housing portion 31, the HDD stops operating. The HDD 42 is one example of the electronic component which is operated by a supply of the power from the battery 34.

The HDD housing portion 32 is disposed in the case 7 and in a middle right end portion of the case 7. Namely, the HDD housing portion 32 is disposed correspondingly with the second opening 12, and exposed to the outside of the case 7 through the second opening 12.

The opening 13 has a second support wall 43. The second support wall 43 extends in the opening 13 toward the inside of the opening 13 from an opening edge that is adjacent to the HDD housing portion 32. The second support wall 43 is recessed from the lower wall 7f of the case 7 toward the inner side of the thickness direction of the case 7 by a distance equal to the thickness of the HDD cover 23, and extends in parallel with the lower wall 7f of the case 7.

A pair of engagement recesses 44a, 44b are disposed in a right end portion of the second support wall 43. The engagement recesses 44a, 44b are engagement holes that are recessed toward the outside of the HDD housing portion 32. A screw hole 45 is disposed in a left end portion of the second support wall 43.

As shown in FIG. 2, the HDD housing portion 32 has a bottom wall 46 and a side wall 47. The bottom wall 46 is an inner wall that separates the HDD housing portion 32 from the internal space of the case 7. A power source connector and interface connector which are not shown are disposed in the bottom wall 46. The HDD 42 is placed on the bottom wall 46 so that the HDD is housed in the HDD housing portion 32. The HDD 42, which is housed in the HDD housing portion 32 is electrically connected to the power source of the body 2 and a circuit board through the connectors. The side wall 47 extends from a peripheral edge of the bottom wall 46 toward the second support wall 43, and is connected to the tip end of second support wall 43.

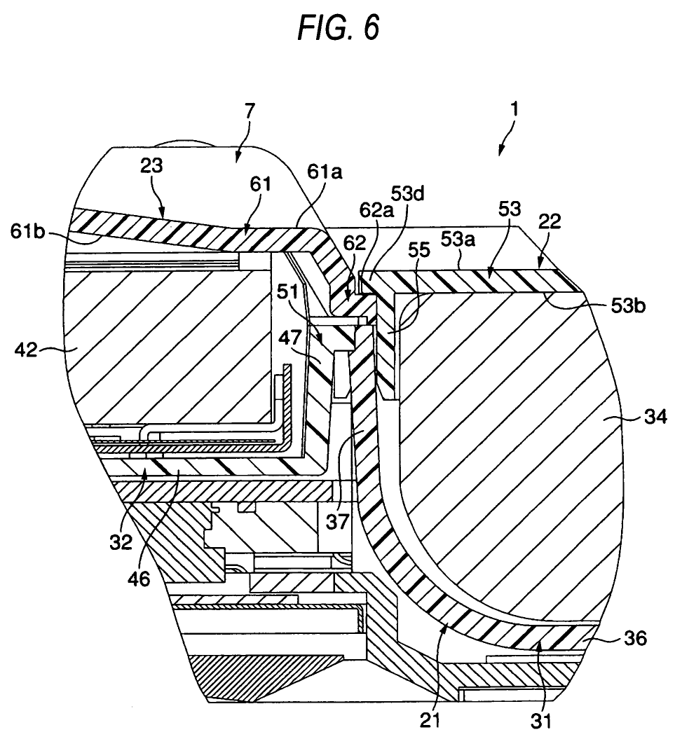

As shown in FIGS. 2 and 6, a portion of the side wall 47 of the HDD housing portion 32, which is opposed to the front wall 7b of the case 7 and a portion of the side wall 37 of the battery housing portion 31, which is opposed to the rear wall 7e of the case 7, form a partition wall 51 together. The partition wall 51 divides the housing portion 21 into the battery housing portion 31 and the HDD housing portion 32.

As shown in FIG. 2, the battery cover 22 is detachably attached to the case 7. The battery cover 22 is a lid that can be freely detached by the user. The battery cover 22 is formed into a rectangular shape that corresponds to the first opening 11.

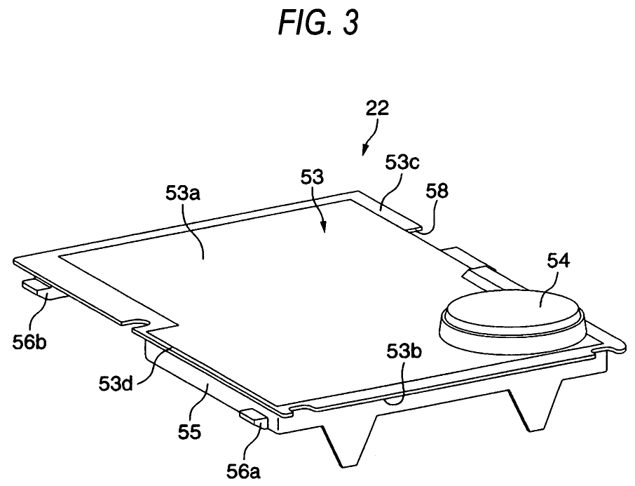

As shown in FIGS. 2 and 3, the battery cover 22 has a lid body 53, a leg portion 54, and an upstanding wall 55. As shown in FIG. 6, the lid body 53 has a surface 53a and a rear face 53b. When the battery cover 22 is attached to the case 7, the surface 53a and an outer face 7fa of the lower wall 7f of the case 7 constitute a part of the outer surface of the case 7. The leg portion 54 is disposed on the surface 53a. The leg portion 54 is a cylindrical projection, and placed on, for example, a desk when the portable computer 1 is used.

When the battery cover 22 is attached to the case 7, the rear face 53b of the lid body 53 is exposed to the interior of the case 7. In the lid body 53, when the battery cover 22 is attached to the case 7, an edge portion 53c excluding the rear edge is placed on the first support wall 35. Since the first support wall 35 has the step with respect to the lower wall 7f of the case 7, the surface 53a of the battery cover 22, which is placed on the first support wall 35 is positioned coplanarly with the outer face 7fa of the lower wall 7f.

In the rear face 53b of the lid body 53, the upstanding wall 55 is formed on a portion that is inside a peripheral edge portion. The upstanding wall 55 upstands from the rear face 53b of the lid body 53 to the direction opposite to the surface 53a, or toward the inside of the case 7. The upstanding wall 55 is disposed on a substantially entire circumference of the lid body 53.

As shown in FIGS. 2 and 6, the battery cover 22 holds the battery 34 in a portion which is defined by the rear face 53b of the lid body 53 and the inner circumferential face of the upstanding wall 55. The battery cover 22 holding the battery 34 is attached to the case 7, whereby the battery 34 is housed in the battery housing portion 31. When the battery cover 22 is detached from the case 7, the battery 34 is detached together with the battery cover 22 from the battery housing portion 31. Namely, the battery 34 is attached to and detached from the battery housing portion 31 in accordance with attachment and detachment of the battery cover 22.

As shown in FIG. 3, the battery cover 22 has a pair of claw portions 56a, 56b. The claw portions 56a, 56b are disposed correspondingly with the engagement recesses 39a, 39b of the battery housing portion 31. The claw portion 56a is projected from a wall face of the upstanding wall 55 that is opposed to the rear wall 7e of the case 7, toward the outside of the battery cover 22. The other claw portion 56b is projected from a left end portion of the lid body 53 toward the outside of the battery cover 22.

By contrast, as shown in FIG. 2, a wall face of the upstanding wall 55 that is opposed to the front wall 7b of the case 7 has a pair of guide projections 57a, 57b. The guide projections 57a, 57b are disposed correspondingly with the guide groove 38a, 38b of the battery housing portion 31. The guide projections 57a, 57b are projected from the upstanding wall 55 toward the outside of the battery cover 22. The lid body 53 has a lock engagement portion 58 in a portion corresponding to the locking mechanism 41. The lock engagement portion 58 is engaged with the locking mechanism 41.

As shown in FIG. 2, the HDD cover 23 is detachably attached to the case 7 so as to overlap with an edge portion 53d of a rear end portion of the battery cover 22. The HDD cover 23 is a lid that is not recommended to be freely opened and closed by the user. The HDD cover 23 is formed into a rectangular shape, which corresponds to the HDD housing portion 32.

As shown in FIGS. 2 and 6, the HDD cover 23 has a lid body 61. The lid body 61 has a surface 61a, a rear face 61b, and a step portion 62. When the HDD cover 23 is attached to the case 7, the surface 61a and the outer face 7fa of the lower wall 7f of the case 7 constitute a part of the outer surface of the case 7. A screw hole 63 is disposed in a left end portion of the surface.

When the HDD cover 23 is attached to the case 7, the rear face 61b is exposed to the interior of the case 7. In the rear face 61b, when the HDD cover 23 is attached to the case 7, an edge portion 61d excluding the front edge is placed on the second support wall 43. Since the second support wall 43 has the step with respect to the lower wall 7f of the case 7, the surface 61a of the HDD cover 23 which is placed on the second support wall 43 is positioned coplanarly with the outer face 7fa of the lower wall 7f.

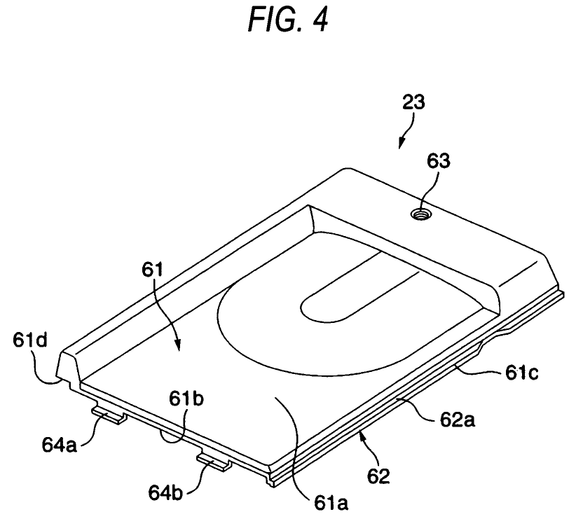

As shown in FIG. 4, a right peripheral edge portion of the lid body 61 has a pair of claw portions 64a, 64b. The claw portions 64a, 64b are disposed correspondingly with the engagement recesses 44a, 44b of the HDD housing portion 32. The claw portions 64a, 64b are projected from the lid body 61 toward the outside of the HDD cover 23.

As shown in FIG. 4, a front peripheral edge portion of the lid body 61 has the step portion 62. The step portion 62 is disposed over a substantially whole of the front peripheral edge portion. As shown in FIG. 6, the step portion 62 extends from the surface 61a of the HDD cover 23 toward the rear face 61b by a distance which is substantially equal to the thickness of the battery cover 22, and further extends from the extension end toward the outside of the HDD cover 23 in parallel with the rear face 61b. In the step portion 62, the upper face of a portion that extends in parallel with the rear face 61b forms a mounting face 62a that supports the battery cover 22.

The HDD cover 23 is attached to the case 7 by engaging the claw portions 64a, 64b with the engagement recesses 44a, 44b of the HDD housing portion 32. The HDD cover 23 is attached to the case 7 so that the peripheral edge portion of the lid body 61 is placed on the second support wall 43, and the step portion 62 is placed on the partition wall 51. Namely, the HDD cover 23 is placed over a range from the second support wall 43 to the partition wall 51.

In a state where the lid body 61 is placed on the second support wall 43, a screw is screwed into the screw hole 45 of the second support wall 43 through the screw hole 63 the HDD cover 23, whereby the HDD cover 23 is fixed to the case 7. According to the configuration, the HDD cover 23 closes the second opening 12, and covers the HDD housing portion 32.

The battery cover 22 overlaps with the HDD cover 23 from the outside of the case 7. The claw portions 56a, 56b of the battery cover 22 are engaged with the engagement recesses 39a, 39b, and then the guide projections 57a, 57b are placed along the guide groove 38a, 38b. According to the configuration, the battery cover 22 closes the first opening 11, and covers the battery housing portion 31.

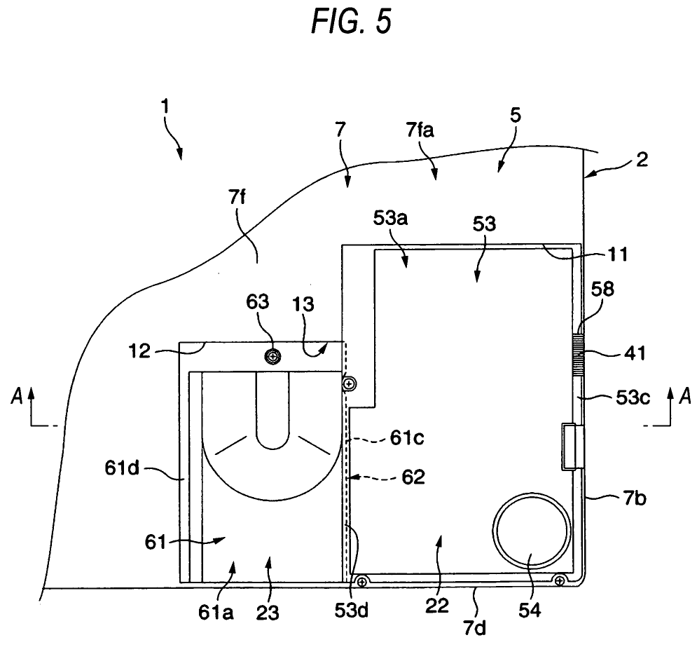

In the battery cover 22, an edge portion 53c excluding the rear edge is placed on the first support wall 35. An edge portion 53d of the rear edge of the battery cover 22 is placed on the step portion 62 of the HDD cover 23. As shown in FIG. 5, namely, the battery cover 22 and the HDD cover 23 are placed so that their adjacent edge portions overlap with each other.

Specifically, adjacent edges of the battery cover 22 and HDD cover 23 that are formed into a rectangular shape overlap with each other. The edge portion 53d of the battery cover 22 in the embodiment overlaps with a substantially whole of an edge portion 61c of the HDD cover 23, which is adjacent to the edge portion 53d. The battery cover 22 is placed over a range from an end portion of the HDD cover 23, which is placed on the partition wall 51, to the first support wall 35.

As shown in FIG. 6, the partition wall 51 is recessed from the lower wall 7f of the case 7 toward the inner side of the thickness direction of the case by a distance equal to the total of the thickness of the battery cover 22 and that of the step portion 62 of the HDD cover 23. Therefore, the mounting face 62a of the step portion 62, which is placed on the partition wall 51 is positioned coplanarly with the upper face of the first support wall 35. Furthermore, the surface 53a of the battery cover 22, which is placed on the mounting face 62a of the step portion 62 is positioned coplanarly with the outer face 7fa of the lower wall 7f.

Next, the function of the portable computer 1 will be described.

As shown in FIG. 6, the step portion 62 of the HDD cover 23 is interposed between the battery cover 22 and the partition wall 51. Therefore, the HDD cover 23 cannot be detached from the case 7 unless the battery cover 22 is detached from the case 7. Namely, the user-openable lid is mounted on the user-unopenable lid, and the user-unopenable lid cannot be directly detached.

According to the thus configured portable computer 1, the area in the case which is occupied by the lids is small, and the case can be miniaturized. As shown in FIG. 5, namely, the battery cover 22 and HDD cover 23 of the portable computer 1 are placed so as to partly overlap with each other. That is, the HDD cover 23 is attached to the case 7 so that the cover overlaps with the edge portion 53d of the battery cover 22. As compared with the case where the battery cover 22 and the HDD cover 23 are juxtaposedly attached to the case 7, therefore, the area required for attachment of the lids 22, 23 is reduced at least by the size of the overlapping portion. Therefore, miniaturization of the case 7 can be attained.

When the edge portion 53d of the battery cover 22 overlaps with a substantially whole of the edge portion 61c of the HDD cover 23 which is adjacent to the battery cover 22, particularly, the area required for attachment of the lids 22, 23 is further reduced, and hence miniaturization of the case 7 can be further attained.

The battery cover 22 that covers the battery housing portion 31 overlaps with the HDD cover 23 that covers the HDD housing portion 32, from the outside of the case 7. Therefore, the HDD housing portion 32 is not opened to the outside of the case 7 unless the battery cover 22 is first detached. The HDD 42 is a component that is less frequently detached than the battery 34. Therefore, the placement in which the battery cover 22 is in the outside improves the usability of the portable computer 1.

The HDD housing portion 32 is a region which is not open to the user. In the portable computer 1 of the embodiment, the HDD cover 23 is mechanically locked by the battery cover 22, and allowed to be removed only after the battery cover 22 is removed. Namely, the HDD housing portion 32 which is not open to the user is configured so as not to be easily opened by an improper user. This contributes to improvement of the reliability of the portable computer 1.

In the portable computer 1, as described above, the lock is formed by the battery cover 22 and the HDD cover 23, and it is not required to dispose an additional locking mechanism or the like. This contributes to improvement of high-density packaging, productivity, and cost reduction of the portable computer 1.

In the case where the second functional component is a component that stops operating when the first functional component is detached from the first housing portion, the security of the portable computer is improved because of the following reason. In a case where the second functional component is detached, it is often that, already, the first lid is removed and the first functional component is detached.

When the first functional component is held by the first lid, this effect is further enhanced. When the second functional component is detached, namely, the first lid is always already detached. In the case where the first functional component is held by the first lid, when the second functional component is detached, the first functional component is surely already detached from the first housing portion.

When the HDD 42 is to be detached, for example, the battery 34 is previously removed. Namely, an erroneous work of detaching the HDD 42 during a period when the HDD 42 is operated can be surely prevented from occurring. In other words, the portable computer 1 can cause a person who is to conduct a work of detaching the HDD 42, to first detach the battery 34 before the HDD 42 is detached.

The case 7 has the first support wall 35 and the second support wall 43, and the HDD cover 23 has the step portion 62. Therefore, the battery cover 22 and the HDD cover 23, which overlap with each other can be surely attached to the case 7.

In the above, the portable computer 1 of the embodiment has been described. Of course, the invention is not restricted to this. For example, the second housing portion may be a card housing portion that is to house a memory card. In the case where the first housing portion is the battery housing portion 31, for example, the battery 34 is always already detached when a memory card is added to the second housing portion. Therefore, there is no possibility that the memory card is contacted with a memory expansion connector or the like to which the power source is supplied, and the security of the user can be enhanced. The kinds of the components which are to be housed in the first and second housing portions are not particularly restricted.

In addition, the battery 34 may be integrally formed with the battery cover 22, and the HDD 42 may be integrally formed with the HDD cover 23.

The first and second lids are not required to overlap with each other in a substantially whole of one edge. When the lids are placed so that they partly overlap with each other, the case 7 can be miniaturized. An electronic apparatus to which the invention can be applied is not restricted to a portable computer. The invention can be applied to any kind of an electronic apparatus such as a portable telephone, a digital camera, a video camera, or a personal digital assistant.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

What is claimed is:

1. An electronic apparatus comprising:
a case including a first opening, and a second opening adjacent to the first opening;
a first lid that is detachably attached to the case and configured to close the first opening, the first lid including a first edge portion; and
a second lid that is detachably attached to the case and configured to close the second opening, while overlapping with at least a part of the first edge portion of the first lid that is attached to the first opening.

2. The electronic apparatus according to claim 1,
wherein the second lid includes a second edge portion adjacent to the first edge portion, and
wherein the first edge portion overlaps with a substantially whole of the second edge portion.

3. The electronic apparatus according to claim 1, further comprising:.
a first housing portion that is disposed in the case and exposed to an outside of the case through the first opening;
a first functional component that is detachably housed in the first housing portion;
a second housing portion that is disposed in the case and exposed to the outside of the case through the second opening; and
a second functional component that is detachably housed in the second housing portion,
wherein a part of the first lid overlaps with the second lid from the outside of the case.

4. The electronic apparatus according to claim 3, wherein the first functional component is held by the first lid, and attached to and detached from the first housing portion in accordance with attachment and detachment of the first lid.

5. The electronic apparatus according to claim 4, wherein the first functional component includes a battery, and the second functional component includes an electronic component that is operated by a supply of a power from the battery.

6. The electronic apparatus according to claim 3, wherein the first functional component is integrally formed with the first lid.

7. An electronic apparatus comprising:
a case including an opening;
a housing portion that is disposed in the case and exposed to an outside of the case through the opening, the housing portion including a partition wall that divides the housing portion into a first housing portion and a second housing portion;
a first lid that is detachably attached to the case and configured to close the first opening, the first lid including a first end portion; and
a second lid that is detachably attached to the case and configured to close the second opening, the second lid including a second end portion adjacent to the first end portion,
wherein at least a part of the first end portion and at least a part of the second end portion are overlapped with each other.

8. The electronic apparatus according to claim 7, wherein the first lid overlaps with the second lid from the outside of the case.

9. The electronic apparatus according to claim 8, further comprising:
a first functional component that is held by the first lid to be attached to and detached from the first housing portion in accordance with attachment and detachment of the first lid; and
a second functional component that is detachably housed in the second housing portion.

10. The electronic apparatus according to claim 9, wherein the first functional component includes a battery, and the second functional component includes an electronic component that is operated by a supply of a power from the battery.

11. The electronic apparatus according to claim 9,
wherein the opening includes:
a first opening edge that is adjacent to the first housing portion;
a first support wall that extends toward an inside of the opening from the first opening edge;
a second opening edge that is adjacent to the second housing portion; and
a second support wall that extends toward the inside of the opening from the second opening edge,
wherein the second lid extends from the second support wall to the partition wall so that the second end portion is disposed on the partition wall, and
wherein the first lid extends from the second end portion to the first support wall.

12. The electronic apparatus according to claim 11, wherein the second end portion has an upper face that is disposed coplanarly with an upper face of the first support wall.

13. The electronic apparatus according to claim 9, wherein the first functional component is integrally formed with the first.
